(19) United States
(12) Patent Application Publication
(10) Pub. No.: US 2002/0088544 A1
(43) Pub. Date: Jul. 11, 2002

(54) Substrate processing apparatus

(75) Inventors: Issei Ueda, Kumamoto-Ken (JP); Yoichi Deguchi, Tokyo-To (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: TOKYO ELECTRON LIMITED, Tokyo (JP)

(21) Appl. No.: 10/032,071

(22) Filed: Dec. 31, 2001

(30) Foreign Application Priority Data
Jan. 10, 2001 (JP) 2001-002515

(51) Int. Cl. C23F 1/00; C23C 16/00

(52) U.S. Cl. 156/345.31; 118/719

(57) ABSTRACT

A plurality of multi-staged heating process unit groups having units relating to heating process on upper stages and units relating to temperature controlling on lower stages are disposed in line with a moving direction of a sub-transfer mechanism provided in a cassette station. By taking out a wafer from a temperature controlling unit with using a sub-transfer mechanism after performing a heating process at a heating unit followed by a temperature controlling process at the temperature controlling unit, throughput is improved. Furthermore, since the transfer of the wafer from the temperature controlling unit and the cassette station is always performed by the sub-transfer mechanism, heat history of each wafer becomes uniform.

### BACKGROUND OF THE INVENTION

1. Field of the Invention

The present invention relates to a substrate processing apparatus such as a coating and developing processing apparatus which applies resist solution onto and develops a substrate such as a semi-conductor wafer and the like.

2. Description of the Related Art

In a photo-resist step in a process of semiconductor device fabrication, for example, after an exposure to a pattern, a temperature controlling process is performed after a substrate such as a semiconductor wafer (hereinafter referred to as a “wafer”) is subject to a heating process and then a developing process is being performed thereon. This kind of process is conventionally performed in a coating and developing processing apparatus.

FIG. 9 is a plan view showing a conventional embodiment of such a processing unit. A coating and developing processing apparatus 100 has a structure that a cassette station 10, a processing station 11 and an interface section 12 are integrally connected. The cassette station 10 is provided, for example, as an access portion of the wafer W with outside. The processing station 11 performs a predetermined process for the wafer w one by one in a coating and developing step. An interface section 12 transfers the wafer W between the processing station 11 and an aligner 30 is provided adjacent thereto. The cassette station 10 has a wafer cassette CR capable of storing a plurality of wafer Ws and a transfer mechanism 21 delivering the wafer W between the cassette CR and the processing station 11. The processing station 11 has a coating unit group 13 structured in two stages for applying regist to the wafer W, a developing unit group 14 structured in two stages for developing wafer W after exposure, a processing unit group 15, and 16 of eight stages for heating or controlling temperature and a main transfer mechanism 22 for transferring the wafer W to and from each unit group 13 to 16. The interface section 12 has a movable pickup cassette CR disposed in two stages of top and bottom, a fixed-type buffer cassette BR and a transfer mechanism 23 for delivering the substrate between the processing station 11 and an aligner.

In this coating and developing processing apparatus 100, after the wafer W is transferred from a cassette station 10 to a processing station 11, each of the predetermined processes such as applying resist is performed respectively. The wafer W is transferred to a processing station 11 through an interface station 12 to an aligner 30 where an exposure process is performed. After that, the wafer W is transferred in a reverse path, from the aligner 30 to the processing station 11 through the interface station 12. Each of the predetermined processes is performed respectively thereon and lastly the wafer is returned to the cassette station 10.

After an exposing process, for example, the wafer is heat processed in a heating unit belonging to a processing unit group 15. The wafer is then being temperature controlled in the temperature controlling unit belonging to the processing unit group 15 and returned to the cassette station 10.

However, in one of multi-staged processing unit group 15, an extension unit is provided as a holding portion for a transfer mechanism 21 to access the processing station 11. After the last temperature controlling process is performed in the processing unit group 15, the wafer is temporarily transferred to the extension unit to wait before being taken out by the transfer mechanism 21 and returned to the cassette station 10, causing time to be wasted in the extension unit.

In addition, for example, in a processing unit group 15 as described above, a main transfer mechanism 22 mainly transfers the substrate from the heating process unit to the temperature controlling unit, however, in some cases, the substrate is transferred by the transfer mechanism 21. Since the temperature of the main transfer mechanism 22 and the transfer mechanism 21 is different, heat history of each substrate may become different.

### SUMMARY OF THE INVENTION

An object of the present invention is to provide a substrate processing apparatus capable of improving through-put without having to wait after a temperature controlling process, and also enabling to provide uniform heat history for each substrate.

In order to achieve the above objects, an apparatus related to main object of the present invention comprises a plurality of temperature controlling portions arranged in one direction adjusting a substrate to a predetermined temperature, a plurality of heating portions disposed near each of said plurality of temperature controlling portions, performing a heating process for the substrate, a first transfer mechanism transferring the substrate between the plurality of temperature controlling portions and the plurality of heating portions, a housing accommodating the substrate processed in the plurality of temperature controlling portions and the plurality of heating portions, and a second transfer mechanism transferring the substrate between the plurality of temperature controlling portions and the housing.

An apparatus related to another object of the present invention comprises a first processing portion having a plurality of temperature controlling portions arranged in one direction controlling a temperature of a substrate, a second processing portion having a plurality of heating portions provided near each of said plurality of temperature controlling portions, performing a heating process for the substrate, a third processing portion having a plurality of coating portions applying a processing solution onto the substrate and a plurality of developing portions developing the coated processing solution, and the coating portions and the developing portions are being arranged in one direction, a first transfer mechanism transferring the substrate between the first processing portion, the second processing portion and the third processing portion, a housing accommodating the substrate processed in the first processing portion, the second processing portion and the third processing portion, and a second transfer mechanism transferring the substrate between the first processing portion and the housing.

According to this structure, the substrate is transferred directly between the temperature controlling portion to the housing with the second transfer mechanism. Since the substrate is transferred to the housing immediately after the temperature controlling process, resulting in the improved throughput by cutting time for waiting.

In addition, since the transfer of the substrate from the heating portion to the temperature controlling portion is performed by the first transfer mechanism and the transfer of the substrate from the temperature controlling portion to the housing is performed by the second transfer mechanism, heat history of each substrate becomes uniform.

These and other objects, features and advantages of the present invention will become more apparent in light of the following detailed description of a best mode embodiment thereof, as illustrated in the accompanying drawings.

### BRIEF DESCRIPTION OF THE DRAWINGS

FIG. 1 is a plan view showing a total structure of a substrate processing apparatus according to an embodiment of a present invention.

FIG. 2 is a sectional view dividing the apparatus with A-A line as shown in FIG. 1.

FIG. 3 is a sectional view dividing the apparatus with B-B line as shown in FIG. 1.

FIG. 4 is a side view showing a structure of a main transfer mechanism according to an embodiment of a present invention.

FIG. 5 is a plan view showing a temperature controlling unit according to an embodiment of a present invention.

FIG. 6 is a plan view showing a structure of a coating unit according to an embodiment of a present invention.

FIG. 7 is a flow chart showing every processing step of a substrate processing apparatus related to the present invention.

FIG. 8 is a side view showing a delivery step between a processing unit group and the main transfer mechanism as well as a second transfer mechanism.

FIG. 9 is a plan view showing an example of a conventional substrate processing apparatus.

### DETAILED DESCRIPTION OF THE PREFERRED EMBODIMENT

Hereinafter, embodiments of the present invention will be explained with reference to the drawings.

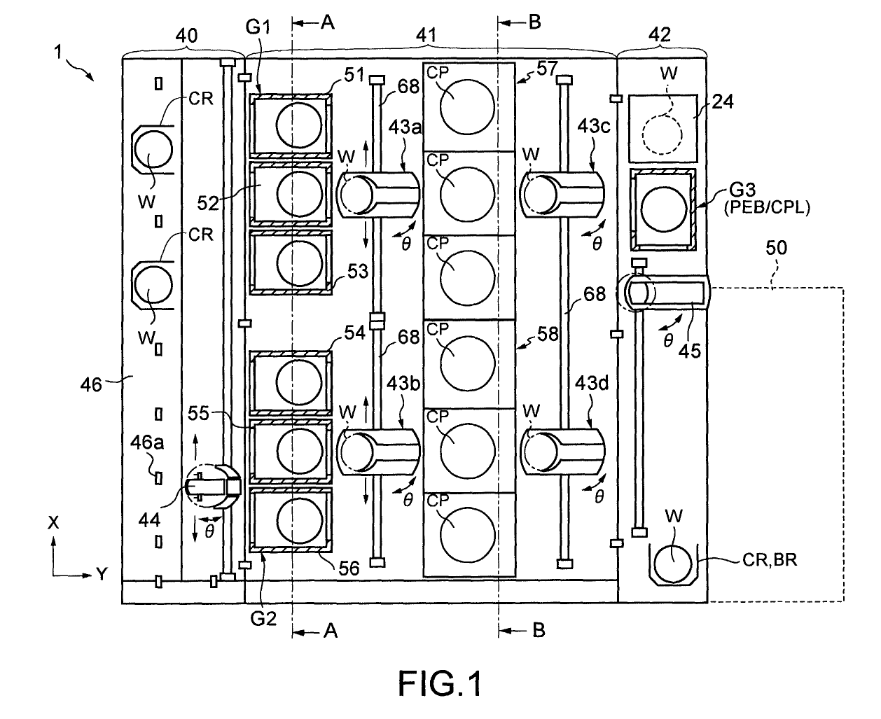

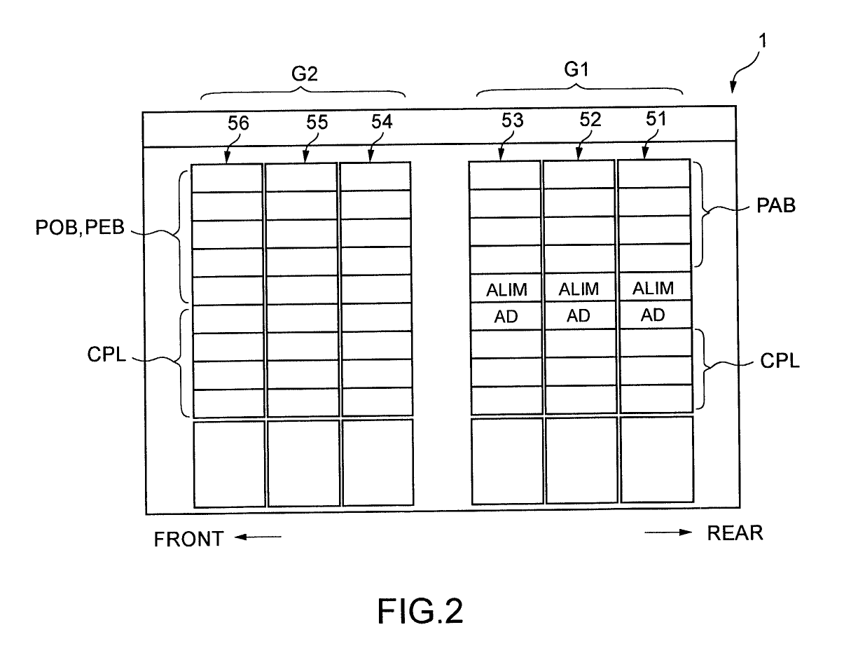

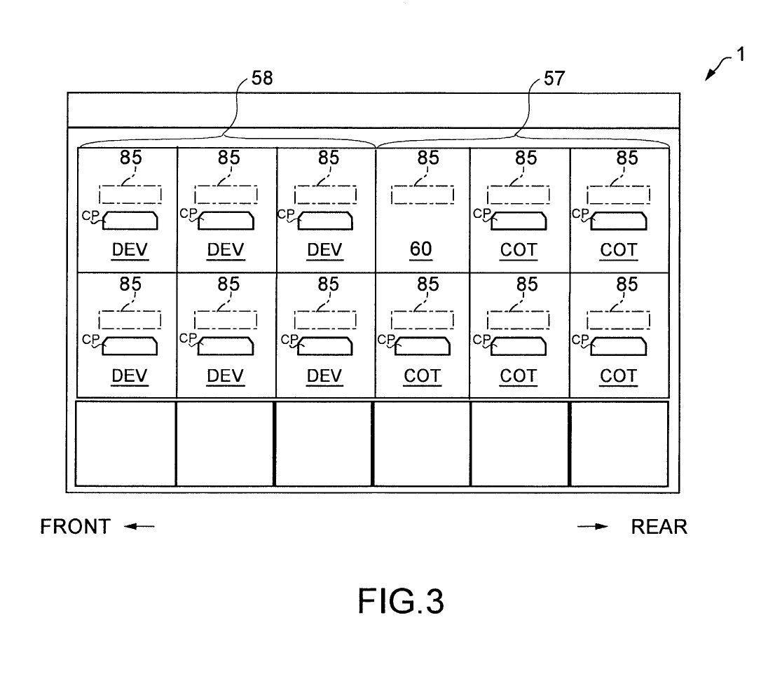

FIG. 1 to FIG. 3 shows a total structure of the coating and developing processing apparatus according to an embodiment of a present invention. FIG. 1 is a plan view, FIG. 2 is a sectional view divided in A-A line in FIG. 1, and FIG. 3 is a sectional view divided in B-B line in FIG. 1.

Referring to FIG. 1, the coating and developing processing apparatus 1 has a structure integrally connecting a cassette station 40, a processing station 41 and an interface station 42. The cassette station 40 carries a wafer cassette CR housing a plurality of, for example, twenty-five wafer Ws as a substrate to be processed in and out from the system disposed for the transfer of the wafer W to and from the wafer cassette CR.

In a processing station 41, three processing units of a first unit group G1, having a plurality of processing units disposed multi-staged in top and bottom direction, is arranged in X-direction, for example, from the cassette station 40 side (a processing unit group 51, 52 and 53) and is placed on a back side of the system. Similarly, three processing units of a second unit group G2, having a plurality of the processing units disposed multi-staged in top and bottom direction, is arranged in X-direction (a processing unit group 54, 55 and 56) and is placed on a front side of the system. Near the center of the processing station 41, a coating unit group 57 applying regist on the wafer W and a developing unit group 58 performing developing process are arranged next to each other in X-direction. A first main transfer mechanism 43a delivering the wafer W between the first unit group G1 and the coating unit group 57 is provided between the first unit group G1 and the coating unit group. A second main transfer mechanism 43b delivering the wafer W between the second unit group G2 and the developing unit group 58 is provided between the second unit group G2 and the developing unit group 58. (In “claims”, the first and the second main transfer mechanism 43a and 43b are defined as “a first transfer mechanism”.) In addition, a third main transfer mechanism 43c and a fourth main transfer mechanism 43d delivering the wafer W to respective unit, the coating unit group 57, the developing unit group 58 and the interface section 42, are provided between the line of coating unit group 57 and the developing unit group 58 and an interface section 42. (In “claims”, the third and the fourth main transfer mechanism 43a and 43b are defined as “a third transfer mechanism”.)

As shown in FIG. 1, in a cassette station 40, a plurality of the wafer cassettes CR, for example up to eight are disposed on a protruding member 46a on the cassette mounting table 46 and placed in line of X-direction, with each of its opening for transferring the wafer facing the side of the processing station 41. A movable first sub-transfer mechanism 44 selectively accesses each wafer cassette CR in cassette arrangement direction. The first sub-transfer mechanism 44 is structured to be able to move in the direction of cassette arrangement (X-direction) and the direction of the arrangement of the wafer (Z-direction, vertical direction). The first sub-transfer mechanism 44 is structured to be able to rotate in θ-direction.

The interface section 42 has the same length as that of the processing station 41 described above in depth (the X-direction), but is structured to be a smaller than the processing station in width. A movable pickup cassette CR and a fixed-type buffer cassette BR are two-staged and disposed at the front of the interface section 42, while an edge exposure unit 23 and the third processing unit group G3 having a multi-staged heating process unit are disposed at the back and a second sub-transfer mechanism 45 are disposed at the center thereof. In the third processing unit group G3, a post-exposure baking unit (PEB) performing a heating process before the development after the exposing process, is disposed, for example, on the top three stages, while a temperature controlling unit (CPL) performing a temperature controlling process after the heating process, is disposed, for example, on the bottom three stages. In addition at least one transferring portion (not shown) for holding the substrate while transferring thereof between the third and the fourth main transfer mechanism 43c and 43d and the second sub-transfer mechanism 45 is provided between, for example, the post exposure baking unit (PEB) and the temperature controlling unit. The second sub-transfer mechanism 45 moves toward X-direction and Z-direction in order to access both cassettes CR, BR and the post exposure baking unit (PEB), and also can be rotated in θ-direction.

As shown in FIG. 2, in both the first processing unit group G1 and the second processing unit group G2, for example, each processing unit is disposed vertically in nine stages from top to bottom. In these processing unit groups 51 to 56, the units relating to the heating process, for example, the pre-baking unit performing heating process after the application of the regist (PAB), a post baking unit performing the heating process after the development (POB) are disposed on the upper stages while the units relating to adjusting a temperature of the substrate by cooling thereof after the heating process, such as the temperature controlling unit (CPL) are disposed on the bottom stages.

In addition, an alignment unit for aligning the wafer W (ALIM) and an adhesion unit for performing a hydrophobic process (AD) are disposed between the units relating to the heating process and the units relating to the temperature controlling.

As shown in FIG. 3, in a coating unit group 57 five coating units (COT) are provided in two stages of top and bottom, in a developing unit group 58 six developing units (DEV) are provided in two stages of top and bottom. In addition, in one of the coating unit group 57, for example, a holding unit 60 is provided for holding the substrate at a time of delivery between the first main transfer mechanism 43a to the third main transfer mechanism 43c.

In the above described manner, the adverse effect of heat influence can be avoided at the time of coating process and developing process, by placing the unit groups relating to the heating process 51 to 56 and the unit groups relating to coating and developing process 57, 58 more apart from each other than a conventional embodiment.

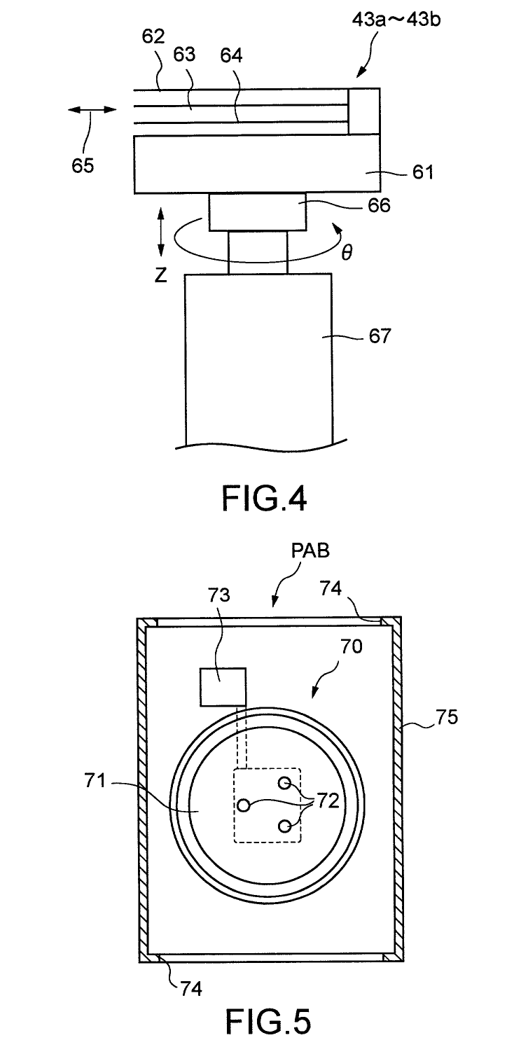

FIG. 4 is a side-view of each main transfer mechanism 43a to 43d. In the main transfer mechanism 43a to 43d the wafer W is transferred with three arms 62, 63 and 64, independently moving laterally in direction shown by the arrow 65, driven by a motor (not shown) provided inside a pedestal 61. Among these three arms, for example, the transfer of the wafer W after the temperature controlling process in the temperature controlling unit (CPL) is performed only with the lower arm 64, a transfer to the units relating to the heating process after the heating process is performed with the upper arm 62 or the middle arm 63 minimizing the heat influence on the wafer.

A rotating rod 66 is fixed to the pedestal 61 and can be rotated in θ-direction with rotation of a driving portion 67. The driving portion 67 is structured such that the rotating rod 66 to rise and lower in a vertical direction (the Z-direction). The main transfer mechanism 43a to 43d are structured to be movable in X-direction with a rail 68 as shown in FIG. 1. A driving mechanism that causes the main transfer mechanism to move to the X-direction is, for example, a belt drive (not shown).

The first sub-transfer mechanism 44 has a driving mechanism same as the main transfer mechanism described above and its arm delivering the wafer W is comprised of, for example, in two stages, the upper and the lower (not shown), however, the number thereof can be three or more.

FIG. 5 is a plan view showing a pre-baking unit belonging to, for example, the first processing group G1 (PAB). A heating apparatus 70 is disposed in the center of the unit. The heating apparatus 70 is comprised of a hot plate 71, three pins 72 and a motor 73. The hot plate 71 heats the wafer W to a predetermined temperature. The three pins 72 penetrates through holes drilled around the center of the heating plate 71, and holds wafer W when transferring thereof at least between one of the first main transfer mechanism 43a and the second transfer mechanism. The motor 73 rises and lowers the pins. In addition, the heating apparatus 70 is surrounded by a casing 75, and an opening portion 74 for carrying the wafer W to and from outside is provided on both sides of the casing 75.

The configuration of a post baking unit (POB) that is, another processing unit relating to heating, and a temperature controlling unit (CPL) are roughly the same as the pre-baking unit (PAB). In addition, temperature controlling in the temperature controlling unit (CPL) is precisely performed by PID control and the like with using, for example, a Peltier element.

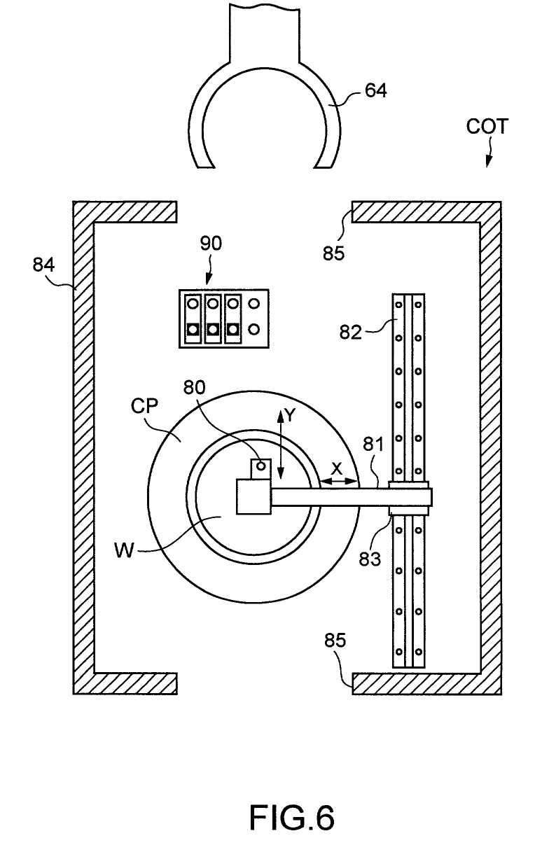

FIG. 6 is a plan view showing a coating unit (COT) belonging to the coating unit group 57. A circular cup CP is provided near the center of the unit and a spin chuck (not shown) is disposed therein. The spin chuck can rise and lower when transferring the wafer W. The spin chuck is structured to rotate by a motor (not shown) with the wafer W being held thereon by a vacuum suction.

A nozzle 80 discharging regist onto the wafer W and is attachable and detachable, is disposed at the end of a nozzle scan arm 81 in the nozzle waiting portion 90 provided on the outside of the cup CP. The nozzle scan arm 81 is attached at an upper end of the vertical support member 83 horizontally movable on the guide rail 82 laid in one direction (Y-direction) outside the cup CP and moves integrally with a vertical support member 83 to Y-direction, being driven by a Y-direction driving mechanism (not shown). In addition, the nozzle scan arm 81 can be moved in X-direction perpendicular to Y-direction, in order to selectively attach and detach the nozzle 80 at the nozzle waiting portion 90 by a X-direction driving motor (not shown).

The resist solution coating apparatus is surrounded by the casing 84 and opening portion 85 carrying in and out the wafer W is provided at both sides of the casing 84.

Further, the explanation on the configuration of the developing unit (DEV) is omitted for it is roughly the same as the configuration of the coating unit (COT). A holding unit is consisted of three pins and a driving portion rising and lowering the pins. In addition, as shown in FIG. 3, the opening portion 85 carrying in and out the wafer W to/from outside is provided on both sides of the casing of holding unit 60 and a casing of the developing unit (DEV) respectively.

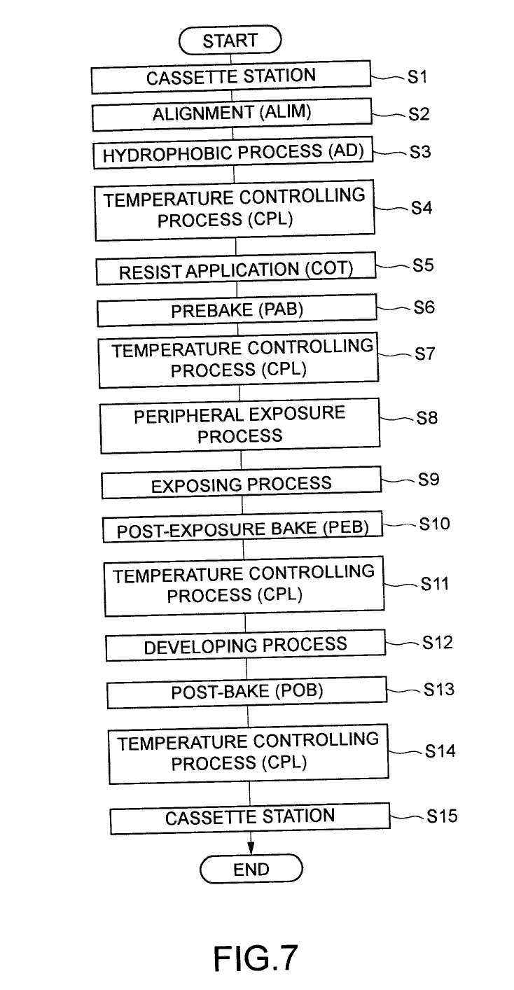

Next, a series of processing step in the coating and developing processing apparatus 1 is explained with reference to the flow chart shown in FIG. 7.

At first, in the cassette station 40, the first sub-transfer mechanism 44 accesses the cassette CR on the cassette mounting table 46 housing wafers before processing. The transfer mechanism takes out the wafer W from the cassette CR (step 1), and transfers the wafer to the alignment unit belonging to the first processing unit group G1 (ALIM). In this case, an alignment unit (ALIM) is arbitrary selected from the unit groups 51 to 53. After being aligned in the alignment unit (step 2), the wafer is transferred to the adhesion unit (AD) with the first main transfer mechanism 43a where the hydrophobic process is performed (step 3). Subsequently in the temperature controlling unit (CPL) of the unit group that the adhesion unit belongs (one of the unit groups 51 to 53) the temperature controlling process is performed at a predetermined temperature, for example, 23° C. (step 4). As described above by performing temperature controlling and heating process in the same unit group, through-put can be improved. After that the wafer is transferred to the resist solution supplying apparatus (COT).

In the resist solution supplying apparatus (COT), referring to FIG. 6, when the wafer W held by the lower arm 64 of the first main transfer mechanism 43a passes the opening portion 85 and transferred to the position right above the cup CP, the spin chuck rises to vacuum suck the wafer W, then lowers, fitting into a predetermined position in the cup CP. The nozzle 80 moves by the scan mechanism of the nozzle scan arm 81 so that the nozzle 80 comes right above the wafer W. And the regist is supplied to the center of the wafer W, and is applied to the whole front surface of the wafer W with a centrifugal force formed by having the wafer W rotate at high-speed (step 5). When supplying of the resist solution is completed, the wafer W is transferred to the pre-baking unit (PAB) with the upper arm 62 or the middle arm 63 of the first main transfer mechanism 43a.

In the pre-baking unit (PAB), referring to FIG. 5, the wafer W held by the arm passes the opening portion 74 and is transferred to the position right above the hot plate 71. The pin 72 rises and receives the wafer W, then lowers to put the wafer on the hot plate 71. The wafer is heated, for example, at a predetermined temperature of, for example, at 100° C., for a predetermined time (step 6). As a result, remaining solvent evaporates and is removed from the coated film on the wafer W. After that, the wafer W is transferred to the nearest temperature controlling unit (CPL) from the above described pre-baking unit (PAB) and the temperature controlling process is performed at a predetermined temperature, for example, 23° C. (step 7).

Then the wafer W is transferred to the third main transfer mechanism 43c through the holding unit 60 by the first main transfer mechanism 43a. The wafer W is transferred to an edge exposure unit 24 where an edge portion thereof is being exposed (step 8). The wafer W is transferred to the second sub-transfer mechanism 45 through a transferring section provided in the post-exposure baking unit (PEB) group, then transferred to the aligner 50 and exposing process is performed (step 9).

After the exposing process, the wafer W is transferred to the post-exposure baking unit (PEB) with the second sub-transfer mechanism 45 again, and is heated for a predetermined time at a predetermined temperature (step 10). The temperature controlling process is performed on the wafer W in the temperature controlling unit provided at the lower stage of the third processing unit group G3 (step 11). Through-put can be improved by performing the heating process and the controlling process in the same unit group.

Next, the wafer W is transferred to a developing unit belonging to the developing unit group 58 (DEV) by the fourth main transfer mechanism 43d and the developing process is performed thereon (step 12).

After that, the wafer W is transferred to the post-baking unit belonging to the second processing unit group G2 (POB), and is heated at a predetermined temperature, for example, 100° C., for a predetermined time (step 13). As a result, the regist swelled in the developing process hardens and chemical resistant of the wafer W improves.

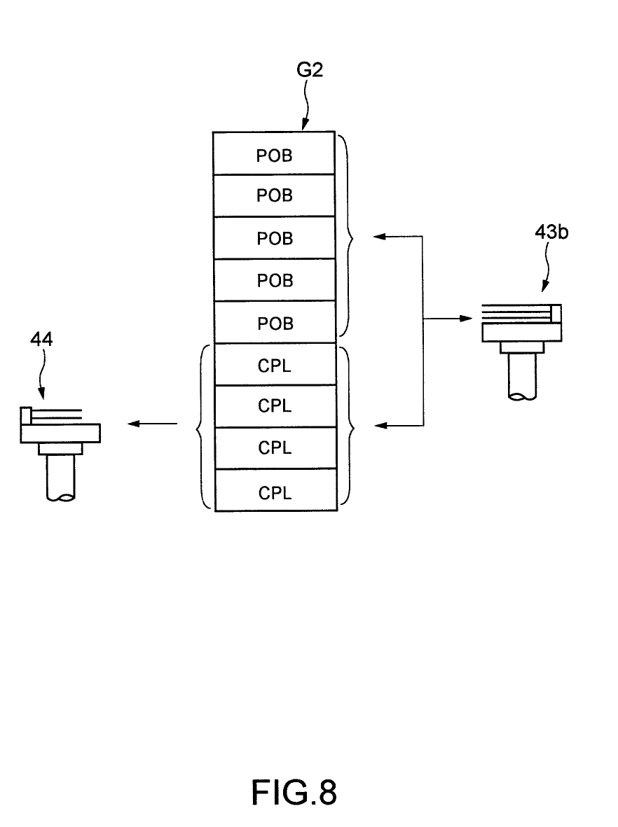

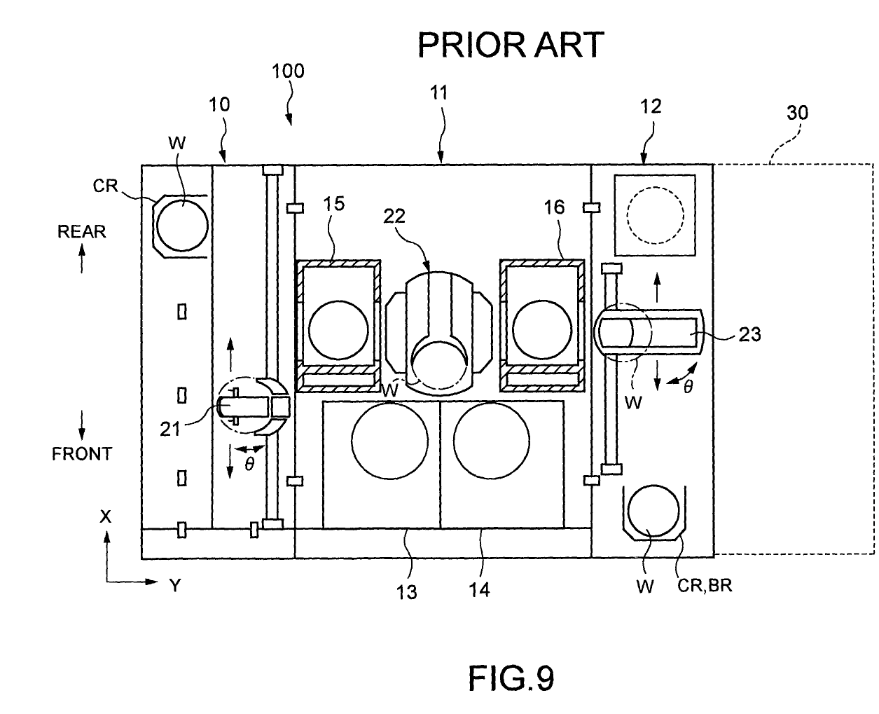

As shown in FIG. 8, the wafer W is transferred to the temperature controlling unit (CPL) of the same unit group as the unit group of the post-baking unit (POB) (one of the unit groups 54 to 56) with the second main transfer mechanism 43b and the temperature controlling process is performed at a predetermined temperature, for example, 23° C. (step 14). Again, through-put can be improved by performing the heating process and the controlling process in the same unit group.

After the predetermined temperature controlling process is completed, the wafer W is taken out by the first sub-transfer mechanism 44 (CPL) to the temperature controlling unit and returned to the cassette station 40 (step 15). As has been described, after the temperature controlling process is completed in the temperature controlling unit of the second processing unit group G2 (CPL), the wafer W is transferred to the cassette station 40 directly by the first sub-transfer mechanism 44, resulting in no time loss caused by waiting, therefore, through-put can be improved.

As explained above, each of the processing unit groups 51 to 56 relating to the heating process and having processing units relating to heating process at its upper stages and processing units relating to controlling temperature on the lower stages are disposed in line with a moving direction of the first sub-transfer mechanism 44 in the cassette station 40. Through-put is improved by having the wafer W temperature controlled at the temperature controlling unit after the heating process is performed in the heating process unit then by taking the wafer W out with the first sub-transfer mechanism 44 from said temperature controlling unit.

In addition, the transfer of the substrate from the processing units relating to the heating process to the temperature controlling unit (CPL) is always performed by the first and the second main transfer mechanism 43a and 43b. As a result heat history of each of the substrates becomes uniform.

The temperature of the wafer W transferred by the first sub-transfer mechanism 44 is always controlled at a constant value with the temperature controlling unit (CPL). For this reason, it is not necessary to separate the use of the two arms in the first sub-transfer mechanism 44 in accordance with the temperature of the transferred wafer W. Thus whichever arm is used, the heat history of the wafer W becomes the same. In addition, the control of the arm becomes easier because the both arms can transfer the wafer.

Furthermore, the main transfer mechanism is provided one each on the two separate processing routes; a processing route before the exposing process and a processing route after the exposing process. As a result, the heat history can be precisely managed.

The present invention is not limited to an embodiment as described above.

In the embodiment explained above, the first sub-transfer mechanism 44 of a cassette station 40 is configured as one, however, the number can be two; one for accessing the first processing unit group G1 and the other for accessing the second processing unit group G2 respectively.

In addition, one of the coating unit groups 57 may be structured to be an anti-reflection film forming apparatus, an apparatus for preventing reflection from the substrate at the time of exposure.

Furthermore, in the present embodiment described above, a coating and developing process apparatus processing a semi-conductor wafer substrate is explained, however, the present invention can be applied to a coating and developing apparatus for processing a glass substrate used for a liquid crystal display instead.

As described above, according to the present invention, the substrate is immediately transferred to the cassette station when the temperature controlling process is completed, resulting in no time loss caused by waiting, therefore, the through-put is improved.

In addition, heat history of each of the substrates becomes uniform, since the main transfer mechanism always transfers the substrate from units relating to heating to units relating to controlling temperature, and the sub-transfer mechanism always transfers the substrate from the temperature controlling units to the cassette station.

The disclosure of Japanese Patent Application No. 2001-00215 filed Jan. 10, 2001 including specification, drawings and claims are herein incorporated by reference in its entirety.

Although only some exemplary embodiments of this invention have been described in detail above, those skilled in the art will readily appreciated that many modifications are possible in the exemplary embodiments without materially departing from the novel teachings and advantages of this invention. Accordingly, all such modifications are intended to be included within the scope of this invention.

What is claimed is:

1. A substrate processing apparatus, comprising:
a plurality of temperature controlling portions arranged in one direction adjusting a substrate to a predetermined temperature;
a plurality of heating portions disposed near each of said plurality of temperature controlling portions, performing a heating process for the substrate;
a first transfer mechanism transferring the substrate between the plurality of temperature controlling portions and the plurality of heating portions;
a housing accommodating the substrate processed in the plurality of temperature controlling portions and the plurality of heating portions; and
a second transfer mechanism transferring the substrate between the plurality of temperature controlling portions and the housing.

2. The apparatus as set forth in claim 1, further comprising:
a first casing surrounding each of said plurality of temperature controlling portions, having a first opening and a second opening for transferring the substrate between the first transfer mechanism and the second transfer mechanism respectively; and
a second casing surrounding each of said plurality of heating portions, having a third opening for transferring the substrate to and from the first transfer mechanism.

3. The apparatus as set forth in claim 1,
wherein each of the plurality of temperature controlling portions is disposed in a lower part of each of the plurality of heating portions.

4. The apparatus as set forth in claim 1,
wherein the second transfer mechanism is disposed between the plurality of said temperature controlling portions and the housing, capable of moving laterally parallel to the arrangement direction of the temperature controlling portions.

5. A substrate processing apparatus, comprising:
a first processing portion having a plurality of temperature controlling portions arranged in one direction controlling a temperature of a substrate;
a second processing portion having a plurality of heating portions provided near each of said plurality of temperature controlling portions, performing a heating process for the substrate;
a third processing portion having a plurality of coating portions applying a processing solution onto the substrate and a plurality of developing portions developing the coated processing solution, and the coating portions and the developing portions are being arranged in one direction;
a first transfer mechanism transferring the substrate between the first processing portion, the second processing portion and the third processing portion;
a housing accommodating the substrate processed in the first processing portion, the second processing portion and the third processing portion; and
a second transfer mechanism transferring the substrate between the first processing portion and the housing.

6. The apparatus as set forth in claim 5, further comprising:
a first casing surrounding each of said plurality of temperature controlling portions, having a first opening and a second opening for transferring the substrate between the first transfer mechanism and the second transfer mechanism respectively.
a second casing surrounding each of said plurality of heating portions, having a third opening for transferring the substrate to and from at least the first transfer mechanism.
a third casing surrounding each of said plurality of coating portions and said plurality of developing portions having a fourth opening for transferring the substrate to and from at least the first transfer mechanism.

7. The apparatus as set forth in claim 5,
wherein the first processing portion is disposed in a lower part of the second processing portion, the first transfer mechanism is disposed between the first processing portion, the second processing portion and the third processing portion, and the second transfer mechanism is disposed between the first processing portion and the housing.

8. The apparatus as set forth in claim 5,
wherein a first arrangement direction of the first processing portion and the second processing portion, and a second arrangement direction of the third processing portion, are equal to a moving direction of the second transfer mechanism.

9. The apparatus as set forth in claim 5, further comprising:
a third transfer mechanism transferring the substrate to the third processing portion;
an interface section being provided between the third transfer mechanism and an aligner performing an exposure process for the substrate after a coating process in the coating portion, transferring the substrate to and from the third transfer mechanism and the aligner.

10. The apparatus as set forth in claim 9,
wherein the third processing portion is disposed between the first transfer mechanism and the third transfer mechanism, and the third processing portion includes at least one holding portion holding the substrate temporarily in at least one of the two situations, when transferring the substrate from the first transfer mechanism to the third transfer mechanism and when transferring the substrate from the third transfer mechanism to the first transfer mechanism.

11. The apparatus as set forth in claim 10,
wherein each of the first processing portion, the second processing portion and the third processing portion is divided into a first group of processing portion and a second group of processing portion, and the first group of processing portion processes the substrate before the exposing process and the second group of processing portion processes the substrate after the exposing process.

12. The apparatus as set forth in claim 11, comprising:
at least two of the first transfer mechanisms;
at least two of the third transfer mechanisms;
wherein each of the transfer mechanisms transfers the substrate to said first group of processing portions and the second group of processing portions correspondingly.
